(19) United States
(12) Patent Application Publication
(10) Pub. No.: US 2012/0193783 A1
(43) Pub. Date: Aug. 2, 2012

(54) PACKAGE ON PACKAGE

(75) Inventors: Ji-Sun HONG, Asan-si (KR); Dae-Young CHOI, Yeosu-si (KR); Mi-Yeon KIM, Yongin-si (KR)

(73) Assignee: SAMSUNG ELECTRONICS CO., LTD., Suwon-si (KR)

(21) Appl. No.: 13/341,125

(22) Filed: Dec. 30, 2011

(30) Foreign Application Priority Data
Feb. 1, 2011 (KR) 10-2011-0010347

(51) Int. Cl. H01L 23/498; H01L 23/522

(52) U.S. Cl. 257/737; 257/758; 257/E23.068; 257/E23.142

(57) ABSTRACT

A package on package is provided herein, the package on package including a first semiconductor package including a first substrate, a first semiconductor chip stacked on the first substrate, a plurality of first connection members on an upper surface of the first substrate and in a first molding material, and a plurality of via holes which respectively expose the plurality of first connection members through the first molding material; a second semiconductor package including a second substrate, a second semiconductor chip stacked on the second substrate, and a plurality of second connection members on a lower surface of the second substrate; and a plurality of connection portions including a plurality of cores and a plurality of conductive fusion layers surrounding the plurality of cores, wherein the plurality of conductive fusion layers contact the upper surface of the first substrate and the lower surface of the second substrate.

### CROSS-REFERENCE TO RELATED APPLICATION

This application claims priority from Korean Patent Application No. 10-2011-0010347 filed on Feb. 1, 2011 in the Korean Intellectual Property Office, and all the benefits accruing therefrom under 35 U.S.C. 119, the contents of which are herein incorporated by reference in their entirety.

### BACKGROUND

1. Field

The present inventive concept relates to a package on package formed by vertically stacking one or more semiconductor packages.

2. Description of the Related Art

Currently, semiconductor packages are being developed to meet requirements such as multi-functionality, high capacity and miniaturization. Accordingly, a system in package (SIP) has been proposed, wherein several semiconductor packages are integrated into one semiconductor package to achieve high capacity and multi-functionality, while significantly reducing the size of the semiconductor package.

The SIPs are largely classified into two types, i.e., a multi-chip package (MCP) formed by stacking several semiconductor chips in one semiconductor package, and a package on package (POP) formed by vertically stacking semiconductor packages which have been individually assembled and have undergone electrical inspection. However, in a manufacturing process of the package on package, high-temperature heat is applied to solder balls positioned between an upper semiconductor package and a lower semiconductor package to connect the upper semiconductor package with the lower semiconductor package. Problems may arise with this process, whereby the solder balls may be separated due to damage, or a short between the neighboring solder balls may occur due to a large amount of flux of the solder balls.

### SUMMARY

According to an aspect of an exemplary embodiment there is provided a package on package including: a first semiconductor package including a first substrate, a first semiconductor chip stacked on the first substrate, a plurality of first connection members on an upper surface of the first substrate and in a first molding material, and a plurality of via holes which respectively expose the plurality of first connection members through the first molding material; a second semiconductor package including a second substrate, a second semiconductor chip stacked on the second substrate, and a plurality of second connection members on a lower surface of the second substrate; and a plurality of connection portions including a plurality of cores and a plurality of conductive fusion layers surrounding the plurality of cores, wherein the plurality of conductive fusion layers contact the upper surface of the first substrate and the lower surface of the second substrate.

The plurality of cores may be formed of a polymer.

The plurality of cores may be positioned closer to the first substrate than the second substrate.

The plurality of cores may be positioned closer to the second substrate than the first substrate.

The plurality of conductive fusion layers may be formed of an alloy of lead and tin.

The first molding material may fill a space between the first semiconductor chip and the first substrate, and the first molding material comprises the plurality of via holes into which the plurality of connection portions is incorporated.

A part of the plurality of connection portions may be included in the via holes.

The first semiconductor chip may be stacked on the first substrate via a plurality of chip bumps, and wherein the plurality of chip bumps include the plurality of cores formed of a polymer, and the plurality of conductive layers surrounds the plurality of cores.

Each of the plurality of connection portions may electrically connect the first semiconductor package and the second semiconductor package to each other, and wherein the first semiconductor package and the second semiconductor package are separated from each other by a predetermined distance.

According to an aspect of an exemplary embodiment there is provided a package on package including: a first semiconductor package including a first substrate, a first semiconductor chip stacked on the first substrate, a plurality of first connection members on an upper surface of the first substrate and in a first molding material, and a plurality of via holes which respectively expose the plurality of first connection members through the first molding material; a second semiconductor package including a second substrate, a second semiconductor chip stacked on the second substrate, and a plurality of second connection members on a lower surface of the second substrate; and a plurality of connection portions formed by fusion of the plurality of first connection members and the plurality of second connection members, wherein each of the plurality of connection portions connect the first semiconductor package with the second semiconductor package, and wherein the plurality of connection portions include a plurality of cores and a plurality of conductive fusion layers surrounding the plurality of cores, and the plurality of conductive fusion layers contact the upper surface of the first substrate and the lower surface of the second substrate.

Each of the plurality of cores may be formed of a polymer.

The package on package of claim 10, wherein each of the plurality of cores is formed of a polymer, and wherein the plurality connection members further includes a plurality of conductive layers which surround the plurality of cores.

The plurality of second connection members may be formed of a same material as the plurality of conductive layers of the plurality of first connection members.

The plurality of conductive fusion layers may be formed by fusion of the plurality of conductive layers of the plurality of first connection members and the plurality of second connection members.

The plurality of conductive layers and the plurality of second connection members are formed of an alloy of lead and tin.

According to an aspect of an exemplary embodiment there is provided a package on package comprising: a first semiconductor package including a first substrate and a first semiconductor chip stacked on the first substrate; a second semiconductor package including a second substrate and a second semiconductor chip stacked on the second substrate; and a plurality of connection portions which electrically connect the first semiconductor package with the second semiconductor package, wherein each of the plurality of connection portions comprises a core and a conductive fusion layer surrounding the core, wherein the conductive fusion layer contacts an upper surface of the first substrate and a lower surface of the second substrate.

Each of the plurality of connection portions further comprises at least one adhesive layer which surrounds the core and is between the core and the conductive fusion layer.

The at least one adhesive layer may be formed of at least one element selected from a group consisting of aluminum (Al), titanium (Ti), vanadium (V), chromium (Cr), manganese (Mn), iron (Fe), copper (Cu), cobalt (Co), nickel (Ni), zirconium (Zr), niobium (Nb), molybdenum (Mo), palladium (Pd), silver (Ag), cadmium (Cd), indium (In), tin (Sn), tantalum (Ta), tungsten (W), platinum (Pt) and gold (Au).

Each of the plurality of connection portions may further include a conductive layer which surrounds the core and is between the at least one adhesive layer and the conductive fusion layer.

The conductive layer may be formed of at least one element selected from a group consisting of aluminum, titanium, vanadium, chromium, manganese, iron, cobalt, nickel, copper, zinc, zirconium, niobium, molybdenum, palladium, silver, cadmium, indium and tin.

### BRIEF DESCRIPTION OF THE DRAWINGS

The above and other aspects will become more apparent by describing in detail exemplary embodiments thereof with reference to the attached drawings, in which:

FIG. 1 is a cross-sectional view of a package on package in accordance with an exemplary embodiment;

FIG. 2 is a cross-sectional view of a first semiconductor package of the package on package in accordance with an exemplary embodiment;

FIG. 3 is an enlarged view for explaining a first connection member of the first semiconductor package, an example of which is shown in FIG. 2;

FIG. 4 is a cross-sectional view showing a process for stacking a second semiconductor package on the first semiconductor package to manufacture the package on package in accordance with an exemplary embodiment;

FIG. 5 is a partial enlarged view of region A of FIG. 1;

FIG. 6 is a cross-sectional view of a package on package in accordance with another exemplary embodiment;

FIG. 7 is a cross-sectional view showing a process for stacking a second semiconductor package on a first semiconductor package to manufacture the package on package in accordance with another exemplary embodiment;

FIG. 8 is a partial enlarged view of region B of FIG. 6;

FIG. 9 is a cross-sectional view of a package on package in accordance with still another exemplary embodiment;

FIG. 10 is a partial enlarged view showing chip bumps of the package on package, an example of which is shown in FIG. 9;

FIG. 11 is a cross-sectional view of a package on package in accordance with still another exemplary embodiment;

FIG. 12 illustrates the shapes of the connecting portions of Experimental example 1; and

FIG. 13 illustrates the shapes of the connecting portions of Comparative example 1.

### DETAILED DESCRIPTION

Features may be understood more readily by reference to the following detailed description of exemplary embodiments and the accompanying drawings, however, many different forms and variations are possible, and the present inventive concept should not be construed as being limited to the exemplary embodiments set forth herein. Like numbers refer to like elements throughout.

It will be understood that when an element or a layer is referred to as being “on” or “connected to” another element or layer, it can be directly on or directly connected to the other element, or intervening elements may also be present. In contrast, when an element is referred to as being “directly on” or “directly connected to” another element, there are no intervening elements present. Like numbers refer to like elements throughout. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

It will be further understood that, although the terms first, second, etc., may be used herein to describe various elements, these elements should not be limited by these terms. These terms are only used to distinguish one element from another element. Thus, for example, a first element, a first component or a first section discussed below could be termed a second element, a second component or a second section without departing from the teachings herein.

Exemplary embodiments are described herein with reference to plan and cross-section illustrations that are schematic illustrations of idealized exemplary embodiments. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing.

Hereinafter, exemplary embodiments will be described in detail with reference to the accompanying drawings.

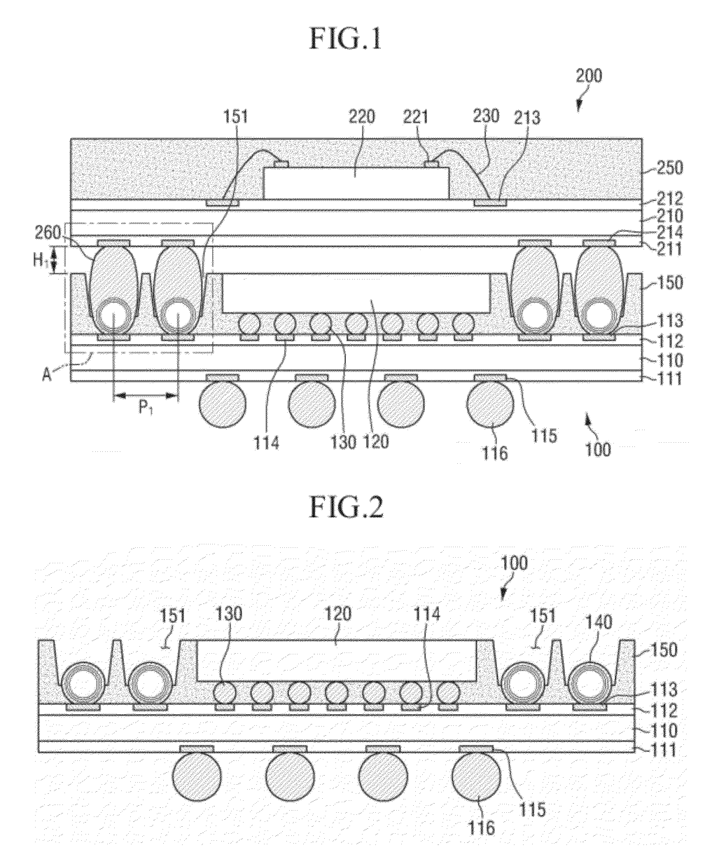

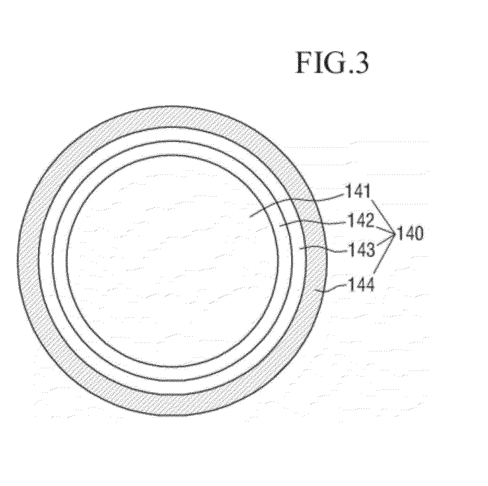

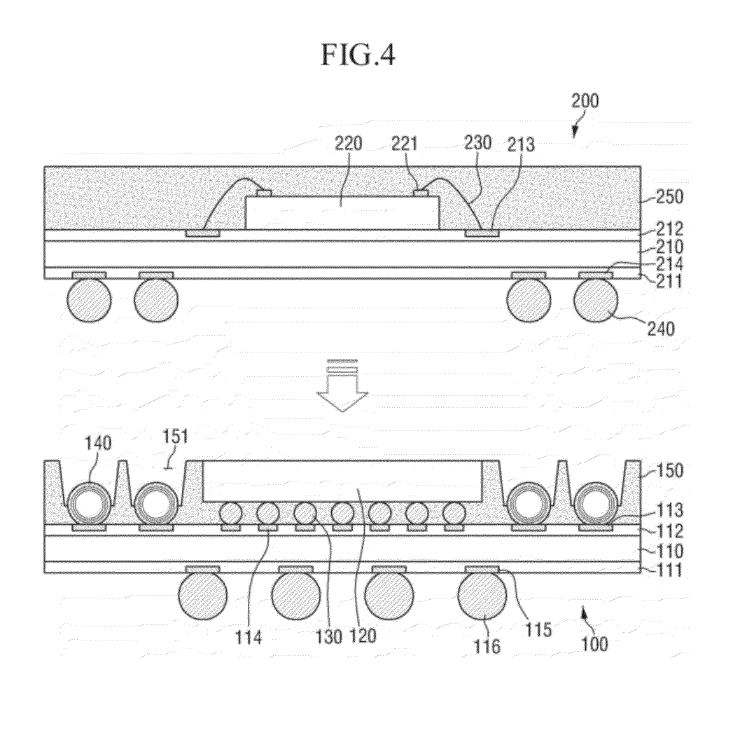

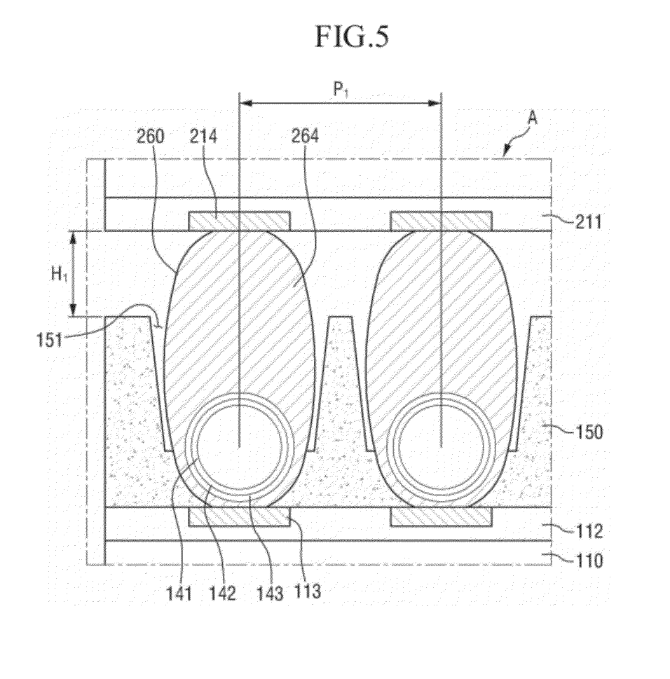

A package on package in accordance with an exemplary embodiment will be described with reference to FIGS. 1 to 5. FIG. 1 is a cross-sectional view of the package on package in accordance with an exemplary embodiment. FIG. 2 is a cross-sectional view of a first semiconductor package of the package on package in accordance with an exemplary embodiment. FIG. 3 is an enlarged view for explaining a first connection member of the first semiconductor package of FIG. 2. FIG. 4 illustrates a process for stacking a second semiconductor package on the first semiconductor package of FIG. 2 to manufacture the package on package in accordance with an exemplary embodiment. FIG. 5 is a partial enlarged view of region A of FIG. 1.

Referring to FIG. 1, the package on package in accordance with the exemplary embodiment includes a first semiconductor package 100, a second semiconductor package 200 and connection portions 260. In this case, the first semiconductor package 100 may be referred to as a lower semiconductor package, and the second semiconductor package 200 may be referred to as an upper semiconductor package.

Referring to FIG. 2, the first semiconductor package 100 in accordance with the exemplary embodiment may include a first substrate 110, a first semiconductor chip 120, chip bumps 130, first connection members 140 and a first molding material 150.

The first substrate 110 may be a substrate for package, e.g., a printed circuit board or ceramic substrate. An upper surface of the first substrate 110 may be divided into a central region to which the first semiconductor chip 120 is attached, and a peripheral region which is arranged outside the central region and used as a region for connection with another package. A lower insulating layer 111 and an upper insulating layer 112 may be respectively formed on the lower surface and the upper surface of the first substrate 110. A plurality of connection pads 115 connected to a plurality of connection terminals 116 may be formed in the lower insulating layer 111. The connection terminals 116 may be components for electrically connecting the semiconductor package with a module board, a main circuit board or the like. The connection terminals 116 may be, e.g., solder balls or conductive bumps. Although a case where the connection terminals 116 are solder balls is illustrated in FIG. 1, it is not limited thereto. The upper insulating layer 112 may include a plurality of connection pads 113 which are arranged in the peripheral region and connected to the first connection members 140, and a plurality of connection pads 114 which are arranged in the central region and connected to the chip bumps 130.

The first semiconductor chip 120 may be located in the central region of the upper surface of the first substrate 110 via the chip bumps 130. The chip bumps 130 may be a specific adhesive agent, e.g., liquid epoxy, adhesive tape or conductive material. FIG. 1 illustrates a case where solder balls are formed as the chip bumps 130 between the first substrate 110 and the first semiconductor chip 120. The first semiconductor chip 120 is electrically connected to the first substrate 110 via the chip bumps 130. The chip bumps 130 may be formed of, e.g., gold, silver, nickel, copper, tin or an alloy thereof, more particularly, copper-nickel-lead (Cu—Ni—Pb), copper-nickel-gold (Cu—Ni—Au), copper-nickel, nickel-gold, nickel-silver or the like.

Although a case where one chip, i.e., the first semiconductor chip 120 is included in the first semiconductor package 100 has been illustrated in this exemplary embodiment, the first semiconductor package 100 may further include one or more semiconductor chips (not shown) vertically stacked on the first semiconductor chip 120.

A plurality of the first connection members 140 may be arranged in the peripheral region of the upper surface of the first substrate 110. The first connection members 140 may connect the first semiconductor package 100 with the second semiconductor package 200 to be described later, and may be arranged corresponding to second connection members 240 of the second semiconductor package 200 (see FIG. 4).

Referring to FIG. 3, each of the first connection members 140 may include a core 141, adhesive layers 142 and 143 and a conductive layer 144. In the semiconductor package in accordance with an exemplary embodiment, a core made of a polymer is formed in the center of each of the connection members. Accordingly, even though heat is applied to the connection members in a bonding process of the connection members, the amount of flux of the connection members is reduced, thereby preventing a short between the connection members. Consequently, it is possible to improve stacking yield. Further, since a short between the connection members is prevented, a pitch between the connection members can be reduced and it is advantageous to miniaturization of the package.

The core 141 is positioned at the center of each of the first connection members 140, and formed of a polymer. The polymer may be, e.g., polyolefin, polycarbonate, polyester, polyamide, polyacrylate, epoxy resin or a blend thereof, but it is not limited thereto. A diameter of the core 141 may be freely adjusted by those skilled in the art. The larger the diameter of the core 141, the smaller the volume of the conductive layer 144.

The adhesive layers 142 and 143 surround the core 141 to improve adhesiveness between the core 141 and the conductive layer 144. The adhesive layers 142 and 143 may be formed of at least one selected from the group consisting of aluminum (Al), titanium (Ti), vanadium (V), chromium (Cr), manganese (Mn), iron (Fe), copper (Cu), cobalt (Co), nickel (Ni), zirconium (Zr), niobium (Nb), molybdenum (Mo), palladium (Pd), silver (Ag), cadmium (Cd), indium (In), tin (Sn), tantalum (Ta), tungsten (W), platinum (Pt), and gold (Au), or a combination thereof, without being limited thereto. The adhesive layers 142 and 143 may be formed in a monolayer or multilayer structure. FIG. 1 illustrates a case where the adhesive layers 142 and 143 have two layers, more particularly, a nickel layer 142 surrounding the core 141 and a copper layer 143 surrounding the nickel layer 142.

The conductive layer 144 may surround the core 141 and the adhesive layers 142 and 143, and may be fused with each of the second connection members 240 to directly connect the first semiconductor package 100 with the second semiconductor package 200. The conductive layer 144 may be formed of at least one selected from the group consisting of aluminum, titanium, vanadium, chromium, manganese, iron, cobalt, nickel, copper, zinc, zirconium, niobium, molybdenum, palladium, silver, cadmium, indium, tin, or a combination thereof. More particularly, the conductive layer 144 may be formed of a solder material such as an alloy of tin and lead.

The first connection members 140 may be formed in a spherical shape or hemispherical shape, without being limited thereto. The first connection members 140 may be formed to have a diameter or height ranging from 100 to 300 μm. In a case where the first connection members 140 are formed to have a diameter within the above range, it is possible to stack the packages while being separated from each other by an appropriate distance, and to improve adhesiveness between the packages. In this case, the conductive layer 144 may be formed to have a thickness ranging from 10 to 30 μm. In a case where the conductive layer 144 is formed to have a thickness within the above range, it is possible to achieve good adhesiveness between the packages and to prevent a short between the connection members. As described above, the volume of the first connection members 140 can be freely adjusted by those skilled in the art by adjusting the diameter of the core 141 and the thickness of the conductive layer 144.

Referring to FIG. 2 again, the first molding material 150 may be formed to fill up a space between the first semiconductor chip 120 and the first substrate 110 to protect the chip bumps 130 and improve adhesivity between the first semiconductor chip 120 and the first substrate 110. Further, the first molding material 150 may serve to protect the semiconductor chip from external physical impact or moisture while maintaining an outer shape of the semiconductor package. The surface of the first molding material 150 may be formed at the same level as the upper surface of the first semiconductor chip 120 or at a lower level than the upper surface of the first semiconductor achip 120, but it is not limited thereto. FIG. 1 illustrates an example in which the first molding material 150 has a surface at substantially the same level as or at a lower level than the upper surface of the first semiconductor chip 120 and the upper surface of the first semiconductor chip 120 is exposed. In this way, in a case where the first molding material 150 has a surface at a lower level than the upper surface of the semiconductor chip, it is possible to reduce a total thickness of the semiconductor package and a total thickness of the stacked packages, to improve heat dissipation characteristics, and to increase resistance against high temperature processing and resistance against bending or torsion. The first molding material 150 may be formed by a molding process using any one of epoxy resin, silicon resin, polyimide and an equivalent thereof.

A plurality of via holes 151 are respectively formed to expose a portion of the first connection members 140 through the first molding material 150. The via holes 151 may be formed by a laser drilling process using a laser. The via holes 151 may be formed in various shapes as far as they expose a portion of the first connection members 140. In case of using laser drilling, it is easier to form the via holes 151 in various shapes.

Referring to FIG. 4, the upper package 200 in accordance with the exemplary embodiment may include a second substrate 210, a second semiconductor chip 220, link members 230, second connection members 240 and a second molding material 250.

The second substrate 210 may have an upper surface and a lower surface arranged opposite to each other and may be a substrate for package, e.g., a printed circuit board or ceramic substrate. The lower surface of the second substrate 210 may be divided into a central region and a peripheral region respectively corresponding to the central region and the peripheral region defined on the upper surface of the first substrate 110. Accordingly, the first semiconductor chip 120 of the first semiconductor package 100 is positioned below the central region defined on the lower surface of the second substrate 210, and the peripheral region defined on the lower surface of the second substrate 210 may be used as a region for connection with the first semiconductor package 100.

A lower insulating layer 211 and an upper insulating layer 212 may be respectively formed on the lower surface and the upper surface of the second substrate 210. A plurality of connection pads 214 connected to the second connection members 240 may be arranged in a region of the lower insulating layer 211 corresponding to the peripheral region of the second substrate 210. The connection pads 214 are arranged to respectively correspond to the connection pads 113 arranged on the upper surface of the first substrate 110 of the first semiconductor package 100 for connection with the first semiconductor package 100. A plurality of connection pads 213 connected to the link members 230 may be formed in the upper insulating layer 212.

The second semiconductor chip 220 may be vertically stacked on the second substrate 210. Specifically, the second semiconductor chip 220 may be attached to the upper surface of the second substrate 210 by a adhesive agent, and electrically connected to the second substrate 210 by the link members 230. FIG. 4 illustrates a case where the link members 230 are conductive wires. Specifically, connection pads 221 arranged on the second semiconductor chip 220 are electrically connected to the connection pads 213 arranged on the second substrate 210 via the conductive wires 230. However, the second substrate 210 may be electrically connected to the second semiconductor chip 220 by interposing solder balls, conductive bumps or the like between the second substrate 210 and the second semiconductor chip 220.

Although a case where one chip, i.e., the second semiconductor chip 220 is included in the second semiconductor package 200 has been illustrated in this exemplary embodiment, the second semiconductor package 200 may include two or more semiconductor chips stacked vertically.

A plurality of the second connection members 240 may be arranged in the peripheral region of the lower surface of the second substrate 210. When the semiconductor package is mounted on another semiconductor package or an external device, the second connection members 240 may facilitate electrical and mechanical contact between the semiconductor packages or between the semiconductor package and the external device. In this exemplary embodiment, the second connection members 240 are connected with the first connection members 140 of the first semiconductor package 100, thereby electrically connecting the first semiconductor package 100 with the second semiconductor package 200. The second connection members 240 may be arranged at positions corresponding to the first connection members 140 formed on the upper surface of the first substrate 110 for connection with the first semiconductor package 100.

The second connection members 240 may be, e.g., solder balls or conductive bumps. FIG. 4 illustrates a case where the second connection members 240 are solder balls. In addition to the second connection members 240 of this exemplary embodiment, various conductors may be used for the same purpose instead of the second connection members 240. The second connection members 240 may be formed of at least one selected from the group consisting of aluminum, titanium, vanadium, chromium, manganese, iron, cobalt, nickel, copper, zinc, zirconium, niobium, molybdenum, palladium, silver, cadmium, indium, tin, tantalum, tungsten, platinum, gold, and lead, or a combination thereof.

The second molding material 250 may be formed on the second substrate 210 to cover the second semiconductor chip 220 and the link members 230, thereby sealing the second semiconductor chip 220 and the link members 230. Although the second molding material 250 is formed to entirely cover the upper surface of the second substrate 210 in this exemplary embodiment, the second molding material 250 may be formed on a part of the upper surface of the second substrate 210 to cover the second semiconductor chip 220 and the link members 230.

Referring to FIG. 4, The connection portions 260 are formed while the second semiconductor package 200 is stacked on the first semiconductor package 100, thereby forming a package on package structure in accordance with the exemplary embodiment.

The connection portions 260 are formed by fusing the first connection members 140 of the first semiconductor package 100 with the second connection members 240 of the second semiconductor package 200, thereby electrically connecting the first semiconductor package 100 with the second semiconductor package 200. Specifically, in order to connect the first semiconductor package 100 with the second semiconductor package 200, heat is applied to the first connection members 140 and the second connection members 240 such that the conductive layers 144 of the first connection members 140 and the second connection members 240 are melted and fused with each other. Accordingly, the conductive layers 144 of the first connection members 140 and the second connection members 240 may be formed of the same material in order to improve the fusion. Particularly, the conductive layers 144 of the first connection members 140 and the second connection members 240 may be formed of a solder material such as an alloy of tin and lead.

As the first connection members 140 are fused with the second connection members 240, a portion of the connection portions 260 are included in the via holes 151. In this case, the portion of the connection portions 260 are completely included in the via holes, and formed not to overflow the via holes.

Referring to FIG. 5, each of the connection portions 260 includes the core 141, the adhesive layers 142 and 143 and a conductive fusion layer 264.

When the first connection members 140 are fused with the second connection members 240, the cores 141 and the adhesive layers 142 and 143 of the first connection members 140 can maintain original shapes at initial positions. Accordingly, the cores 141 and the adhesive layers 142 and 143 of the connection portions 260 are substantially equal to the cores 141 and the adhesive layers 142 and 143 of the first connection members 140 of the first semiconductor package 100. Consequently, the cores 141 and the adhesive layers 142 and 143 in the conductive fusion layers 264 may be positioned closer to the first substrate 110 than the second substrate 210.

The conductive fusion layer 264 is formed by fusing the conductive layer 144 of each of the first connection members 140 with each of the second connection members 240. In the conductive fusion layers 264 of this exemplary embodiment, since the volume of the conductive layers 144 is relatively reduced due to presence of the cores 141 and the adhesive layers 142 and 143, the amount of flow in fusion is reduced and the conductive fusion layers 264 do not overflow the via holes 151, thereby preventing a short between the connection members. Accordingly, it is possible to reduce a pitch between the connection members to thereby contribute to miniaturization of the package. The pitch P₁ means a distance between the connection portions, more particularly, a distance from a center of the core of one conductive fusion layer to a center of the core of the next conductive fusion layer.

The conductive fusion layers 264 may be attached to the upper surface of the first substrate 110 and the lower surface of the second substrate 210 while surrounding the cores 141 and the adhesive layers 142 and 143. The conductive fusion layers 264 may be formed in various forms as far as they connect the first substrate 110 with the second substrate 210 while surrounding the cores 141 and the adhesive layers 142 and 143.

The conductive fusion layers 264 allow the first semiconductor package 100 and the second semiconductor package 200 to be separated from each other by a predetermined distance H₁. That is, the conductive layers 144 of the first connection members 140 are fused with the second connection members 240 to support a space such that the first semiconductor package 100 is separated from the second semiconductor package 200 by the predetermined distance H₁. Accordingly, it is possible to improve the drop reliability of the package on package.

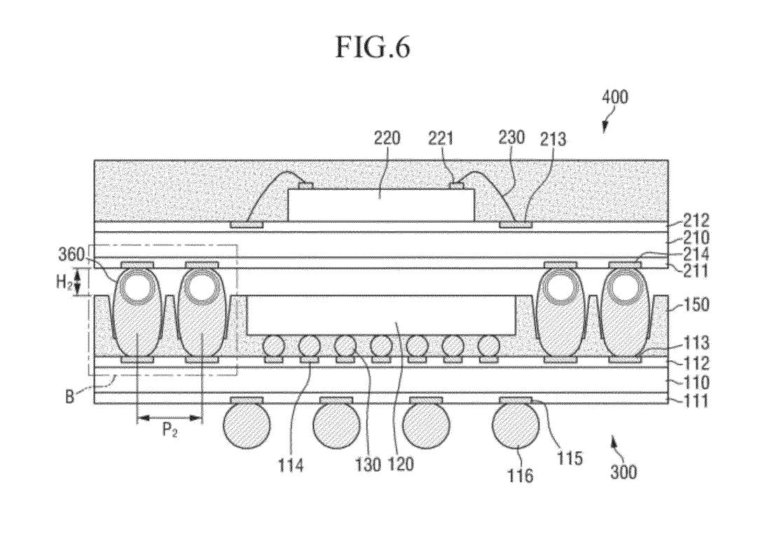

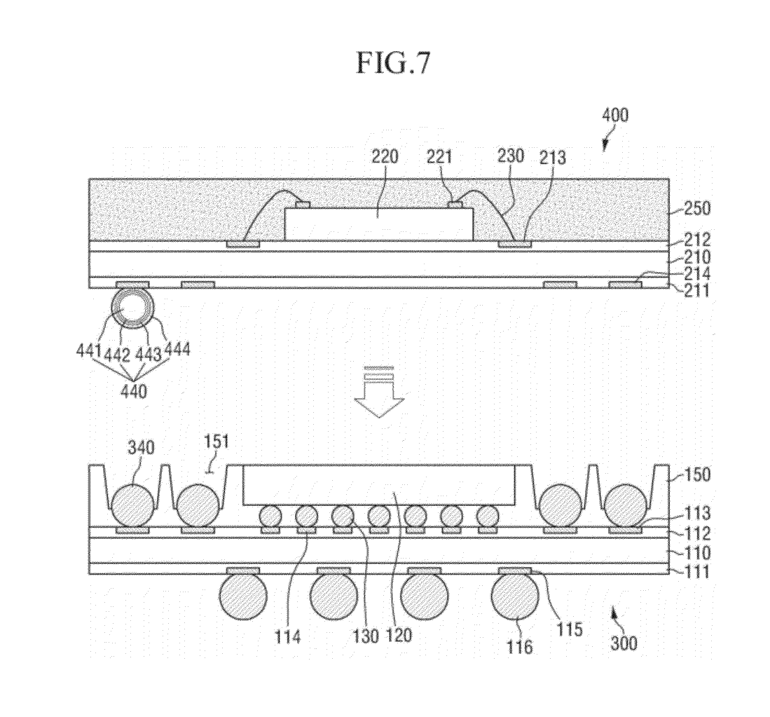

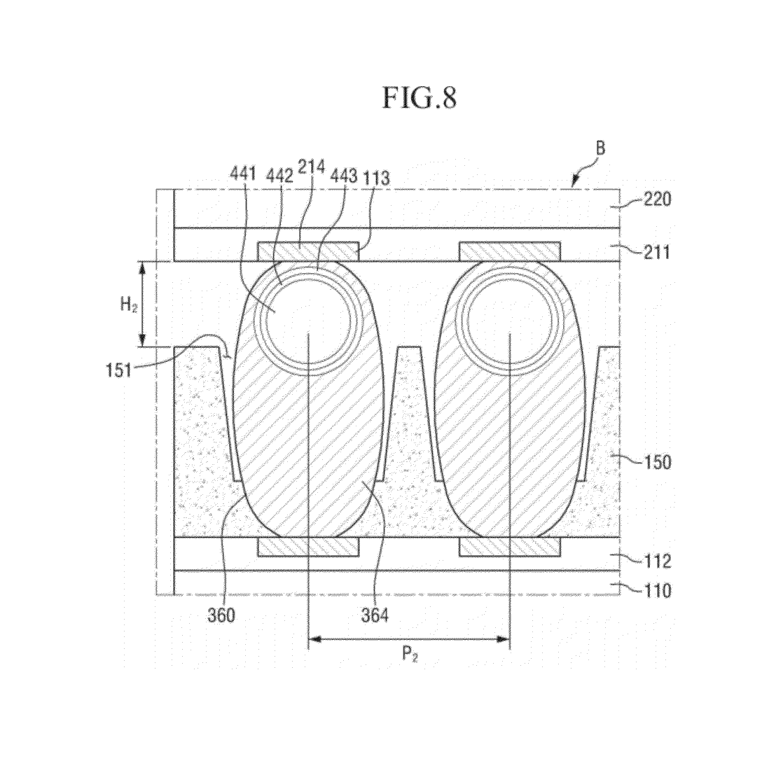

Hereinafter, a package on package in accordance with another exemplary embodiment will be described with reference to FIGS. 6 to 8. FIG. 6 is a cross-sectional view of the package on package in accordance with another exemplary embodiment. FIG. 7 illustrates a process for stacking a second semiconductor package on a first semiconductor package to manufacture the package on package in accordance with another exemplary embodiment. FIG. 8 is a partial enlarged view of region B of FIG. 6.

Referring to FIG. 6, the package on package in accordance with another exemplary embodiment includes a first semiconductor package 300, a second semiconductor package 400 and connection portions 360. Referring to FIG. 7, the connection portions 360 is formed while the second semiconductor package 400 is stacked on the first semiconductor package 300, thereby forming a package on package structure of this exemplary embodiment. In this case, the first semiconductor package 300 may be referred to as a lower semiconductor package, and the second semiconductor package 400 may be referred to as an upper semiconductor package.

Referring to FIG. 7, the first semiconductor package 300 of this exemplary embodiment may include the first substrate 110, the first semiconductor chip 120, the chip bumps 130, first connection members 340, and the first molding material 150. The first semiconductor package 300 of this exemplary embodiment includes the same components as those of the first semiconductor package 100 of FIG. 2 except that the first connection members 340 are formed differently. Accordingly, the same or similar components are designated by the same reference numerals, and a detailed description thereof will be omitted. In this case, the description will be given focusing on the first connection members 340.

A plurality of the first connection members 340 may be arranged in the peripheral region of the upper surface of the first substrate 110. The first connection members 340 are fused with second connection members 440 that will be described later to form the connection portions 360.

The first connection members 340 may be connected to the connection pads 113 formed in the upper insulating layer 112 of the first substrate 110. A portion of the first connection members 340 are exposed by the via holes 151 to facilitate the fusion with the second connection members 440 to be described later.

The first connection members 340 may be, e.g., solder balls or conductive bumps. FIG. 7 illustrates a case where the first connection members 340 are solder balls, but the first connection members 340 may be formed of at least one selected from the group consisting of aluminum, titanium, vanadium, chromium, manganese, iron, cobalt, nickel, copper, zinc, zirconium, niobium, molybdenum, palladium, silver, cadmium, indium, tin, tantalum, tungsten, platinum, gold, and lead, or a combination thereof.

Referring to FIG. 7, the second semiconductor package 400 of this exemplary embodiment may include the second substrate 210, the second semiconductor chip 220, the link members 230, the second connection members 440 and the second molding material 250. The second semiconductor package 400 of this exemplary embodiment includes the same components as those of the second semiconductor package 200 of FIG. 4 except that the second connection members 440 are formed differently. Accordingly, the same or similar components are designated by the same reference numerals, and a detailed description thereof will be omitted. In this case, the description will be given focusing on the second connection members 440.

A plurality of the second connection members 440 are arranged in the peripheral region of the lower surface of the second substrate 210. The second connection members 440 are connected to the connection pads 214 formed in the lower insulating layer 211 of the second substrate 210. Since the second connection members 440 are connected to the first connection members 340 of the first semiconductor package 300, the second connection members 440 may be arranged at positions corresponding to the first connection members 340.

Each of the second connection members 440 includes a core 441, adhesive layers 442 and 443 and a conductive layer 444. The second connection members 440 are substantially the same as the first connection members 140 of the first semiconductor package 100 of the aforementioned exemplary embodiment.

The core 441 is formed of a polymer, particularly, a polymer which can maintain its shape even though heat is applied thereto to melt the conductive layer 444.

The adhesive layers 442 and 443 surround the core 441 and serve to improve adhesiveness between the core 441 and the conductive layer 444. Also, the adhesive layers 442 and 443 serve to prevent elements of each layer from being diffused. The adhesive layers 442 and 443 may be formed in a monolayer or multilayer structure. In a case where the adhesive layers 442 and 443 have a multilayer structure, any one layer may be formed of a material having excellent thermostability. The adhesive layers having excellent thermostability may serve to prevent the polymer from being melted due to heat diffused to the polymer of the core 441 when heat is applied to the second connection members 440.

The conductive layer 444 may be formed to surround the core 441 and the adhesive layers 442 and 443. Since the conductive layer 444 is substantially fused with each of the first connection members 340, the conductive layer 444 may be formed of the same material as that of the first connection members 340.

The connection portions 360 are formed by fusing the first connection members 340 of the first semiconductor package 300 with the second connection members 440 of the second semiconductor package 400. The connection portions 360 support a space such that the first semiconductor package 300 is separated from the second semiconductor package 400 by a predetermined distance H₂.

Each of the connection portions 360 includes the core 441, the adhesive layers 442 and 443 and a conductive fusion layer 364. When the first connection members 340 and the second connection members 440 are melted due to heat and fused with each other, the cores 441 and the adhesive layers 442 and 443 of the second connection members 440 can maintain original shapes at initial positions. Accordingly, the cores 441 and the adhesive layers 442 and 443 of the connection portions 360 are substantially equal to the cores 441 and the adhesive layers 442 and 443 of the second connection members 440. Since the second connection members 440 formed in the second semiconductor package 200 include the cores 441 and the adhesive layers 442 and 443, which can maintain original shapes at initial positions even in fusion, and the first connection members 340 are fused with the conductive layers 444 of the second connection members 440, the cores 441 and the adhesive layers 442 and 443 may be positioned closer to the second substrate 210 than the first substrate 110.

The conductive fusion layers 364 are formed by fusing the first connection members 340 with the conductive layers 444 of the second connection members 440. In a case where the first connection members 340 and the conductive layers 444 are formed of the same material, the first connection member 340 and the conductive layer 444 can be fused into one layer while they are melted due to heat and cooled again. The conductive fusion layers 364 are attached to the upper surface of the first substrate 110 and the lower surface of the second substrate 210 while surrounding the cores 441 and the adhesive layers 442 and 443. Accordingly, the first semiconductor package 300 is electrically connected with the second semiconductor package 400 substantially by the conductive fusion layers 364.

While the first connection members 340 are fused with the conductive layers 444, the conductive fusion layers 364 do not overflow the via holes 151. In other words, since the volume of the conductive layers 444 is relatively reduced due to presence of the cores 441 and the adhesive layers 442 and 443, the flux of the conductive fusion layers 364 during the formation of the connection portions 360 is not excessively generated and, thus, the conductive fusion layers 364 do not overflow the via holes 151. Accordingly, it is possible to prevent a short between the connection members, and reduce a pitch between the connection members. In this exemplary embodiment, a pitch P₂ is maintained between the neighboring connection members.

Although a case where each of the first connection members 340 does not include a core formed of a polymer and only each of the second connection members 440 includes a core has been illustrated in this exemplary embodiment, it is not limited thereto. For example, both the first connection members of the lower semiconductor package and the second connection members of the upper semiconductor package may include cores. In this case, conductive fusion layers can be formed by fusion of conductive layers surrounding the cores respectively. Further, in a case where both the first connection members and the second connection members include cores, the thickness of the conductive layers may be increased while reducing the diameter of the cores in order to facilitate stacking of the packages. In this case, the thickness of the conductive layers may be freely adjusted by those skilled in the art so as to achieve good fusion while preventing the conductive fusion layers from overflowing the via holes.

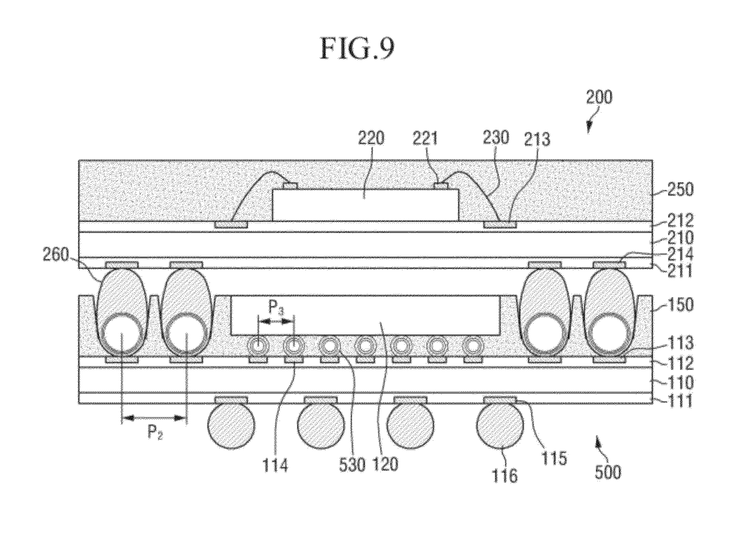

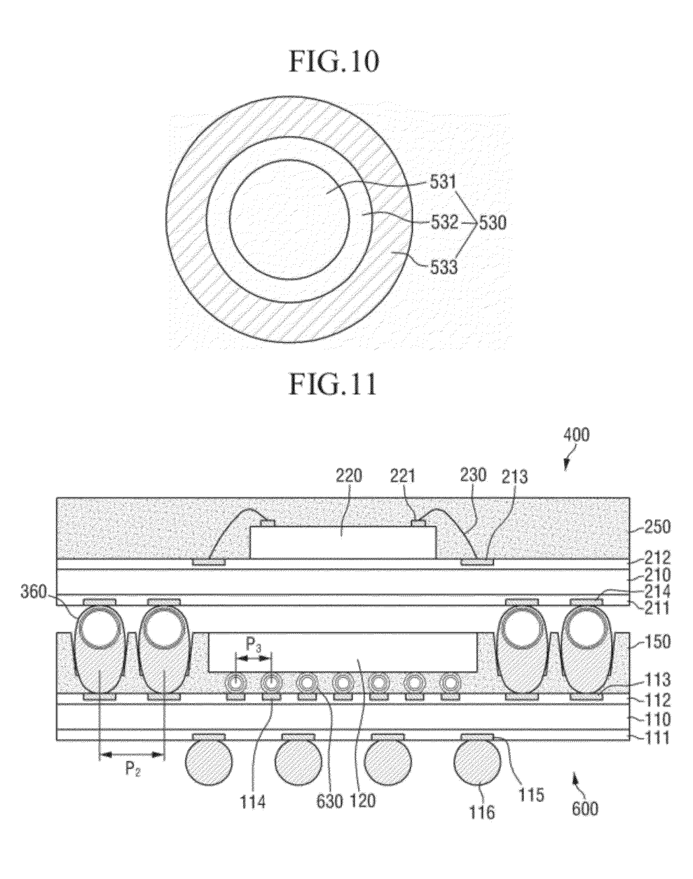

Hereinafter, a package on package in accordance with still another exemplary embodiment will be described with reference to FIGS. 9 and 10. FIG. 9 is a cross-sectional view of the package on package in accordance with still another exemplary embodiment. FIG. 10 is a partial enlarged view showing chip bumps of the package on package of FIG. 9.

Referring to FIG. 9, the package on package in accordance with still another exemplary embodiment includes a first semiconductor package 500, the second semiconductor package 200 and the connection portions 260. The package on package of this exemplary embodiment may be formed by stacking the second semiconductor package 200 on the first semiconductor package 500 via the connection portions 260. The package on package of this exemplary embodiment includes the same components as those of the package on package of FIG. 1 except that chip bumps 530 of the first semiconductor package 500 are formed differently. Accordingly, the description will be given focusing on the chip bumps 530, the same or similar components are designated by the same reference numerals, and a detailed description thereof will be omitted.

The chip bumps 530 may be connected to the connection pads 114 formed in the upper insulating layer 112 of the first substrate 110, and interposed between the first substrate 110 and the first semiconductor chip 120. The chip bumps 530 serve to electrically connect the first substrate 110 with the first semiconductor chip 120.

Referring to FIG. 10, each of the chip bumps 530 includes a core 531, an adhesive layer 532 and a conductive layer 533.

The core 531 may be formed of a polymer and formed in a spherical shape at the center of each of the chip bumps 530, but the shape of the core 531 is not limited thereto. The polymer may be, e.g., polyolefin, polycarbonate, polyester, polyamide, polyacrylate, epoxy resin or a blend thereof, which is well-known in the art. The core 531 may be formed of a polymer having excellent stiffness and thermostability, which is not decomposed when the conductive layer 533 is melted.

The adhesive layer 532 surrounds the core 531 to improve adhesiveness between the core 531 and the conductive layer 533. Further, the adhesive layer 532 may serve to prevent heat from being transferred to the core 531 when the conductive layer 533 is melted due to heat applied to the chip bumps 530 for connection of the first substrate 110 and the first semiconductor chip 120. FIG. 9 illustrates a case where the adhesive layer 532 is formed in a monolayer structure, but the adhesive layer 532 may be formed in a multilayer structure having two or more layers without being limited thereto. The adhesive layer 532 may be formed of at least one selected from the group consisting of aluminum (Al), titanium (Ti), vanadium (V), chromium (Cr), manganese (Mn), iron (Fe), copper (Cu), cobalt (Co), nickel (Ni), zirconium (Zr), niobium (Nb), molybdenum (Mo), palladium (Pd), silver (Ag), cadmium (Cd), indium (In), tin (Sn), tantalum (Ta), tungsten (W), platinum (Pt), and gold (Au), or a combination thereof, without being limited thereto.

The conductive layer 533 may surround the core 531 and the adhesive layer 532, and may be joined to the upper surface of the first substrate 110 and the lower surface of the first semiconductor chip 120 to connect the first substrate 110 with the first semiconductor chip 120. Specifically, when heat is applied to the chip bumps 530, the conductive layer 533 flows and is hardened again so that the first semiconductor chip 120 is connected to the first substrate 110. In the chip bumps 530 of this exemplary embodiment, since the polymer fills up a portion of the chip bumps 530 at the center thereof, the volume of the conductive layer 533 is relatively reduced and the flowing volume is also reduced. Accordingly, it is possible to prevent a phenomenon in which the neighboring chip bumps 530 are connected to each other due to flowing and a short occurs, thereby reducing a pitch P₃ between the chip bumps 530. The pitch P₃ means a distance between the chip bumps 530, more particularly, a distance from a center of the core of one chip bump to a center of the core of the next chip bump. The reduction of the pitch may contribute to miniaturization of the package. The conductive layer 533 may be formed of at least one selected from the group consisting of aluminum, titanium, vanadium, chromium, manganese, iron, cobalt, nickel, copper, zinc, zirconium, niobium, molybdenum, palladium, silver, cadmium, indium, tin, tantalum, tungsten, platinum, gold, and lead, or a combination thereof. More particularly, the conductive layer 533 may be formed of a solder material such as an alloy of tin and lead.

The thickness of the conductive layer 533 may be adjusted by those skilled in the art for sufficient connection of the first semiconductor chip 120 and the first substrate 110. Specifically, the conductive layer 533 may be formed such that a ratio of the conductive layer 533 to the chip bump 530 is greater than a ratio of the core 141 and the conductive layer 144 to the first connection member 140. This is because the chip bumps 530 are not fused with other members whereas the first connection members 140 are fused with the second connection members 240.

Hereinafter, a package on package in accordance with still another exemplary embodiment will be described with reference to FIG. 11. FIG. 11 is a cross-sectional view of the package on package in accordance with still another exemplary embodiment.

Referring to FIG. 11, the package on package of this exemplary embodiment includes a first semiconductor package 600, the second semiconductor package 200 and the connection portions 360. The first semiconductor package 600 includes the first substrate 110, the first semiconductor chip 120, chip bumps 630, the first connection members 140 and the first molding material 150. The package on package of this exemplary embodiment includes the same components as those of the package on package of FIG. 6 except that chip bumps 630 are formed differently. In this case, the chip bumps 630 are substantially the same as the chip bumps 530 of the package on package of FIG. 9.

Each of the chip bumps 630 of this exemplary embodiment includes a core (not shown), an adhesive layer (not shown) and a conductive layer (not shown). Preferably, the conductive layer may be formed of a solder material such as an alloy of tin and lead. Since each of the chip bumps 630 of this exemplary embodiment includes the core formed of a polymer at the center thereof and the adhesive layer surrounding the core, the volume of the conductive layer can be relatively reduced. Further, the volume of the conductive layer flowing when heat is applied to the chip bumps 630 can be adjusted by adjusting the thickness of the conductive layer. Accordingly, it is possible to reduce a pitch P₃ between the chip bumps 630 and it is advantageous to miniaturization of the package.

As described above, in the package on package in accordance with the exemplary embodiments, the connection members including the cores formed of a polymer are used in stacking of the packages. Accordingly, for example, the volume of a solder material can be relatively reduced and the flowing volume of the solder material can be adjusted. Consequently, it is possible to prevent a short between the connection members from occurring due to flowing of the excessive amount of the solder material. Further, it is possible to provide excellent bonding between the connection members and to enhance stacking yield. Furthermore, the connection portions are formed by fusion of the connection members so that the upper package and the lower package can be stacked to be separated from each other by a predetermined distance. Accordingly, it is possible to improve the drop reliability of the package on package.

Hereinafter, the package on package in accordance with the exemplary embodiment will be described by the experiment. This is merely for explanation, and does not impose a limitation on the scope.

<Experiment 1> Evaluation of Wettability

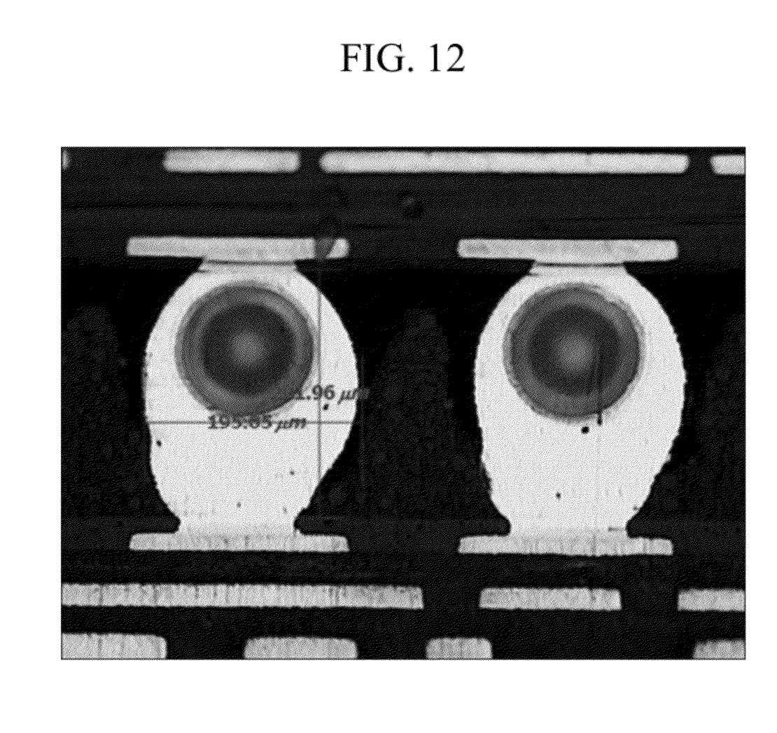

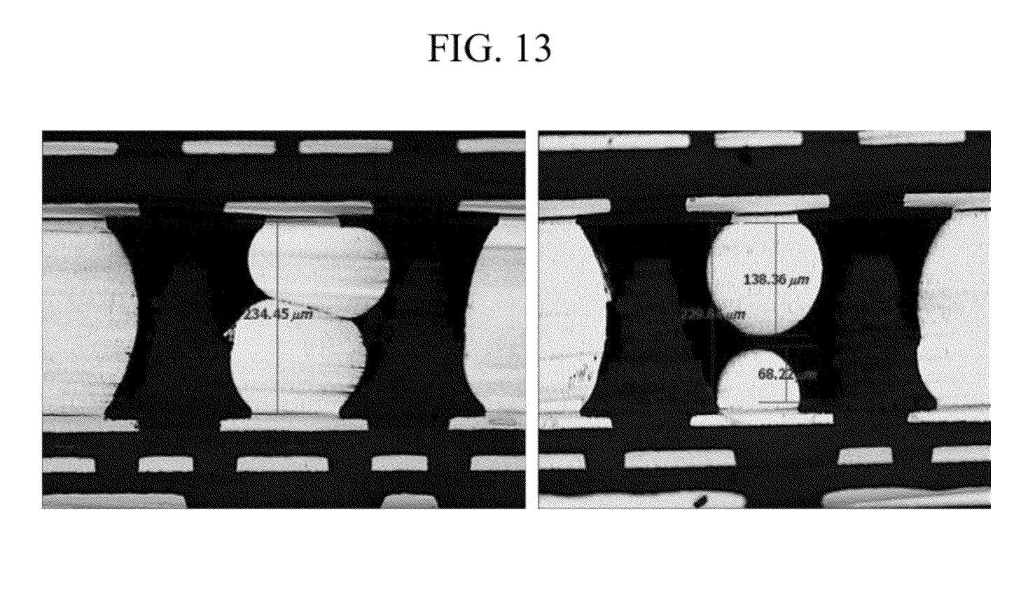

A package on package having the same structure as that of FIG. 6 was manufactured (Experimental example 1). In this case, the first connection members of the lower semiconductor package were formed of an alloy of lead and tin. The second connection members of the upper semiconductor package were manufactured to include cores formed of a polymer, nickel layers surrounding the cores, copper layers surrounding the nickel layers, and solder layers formed of an alloy of lead and tin to surround the copper layers. On the other hand, a package on package, wherein both the first connection members and the second connection members are formed of solder balls, e.g., an alloy of lead and tin to connect the upper semiconductor package with the lower semiconductor package in the same structure as that of FIG. 6, was manufactured (Comparative example 1). One hundred connection portions formed when the upper semiconductor package was connected with the lower semiconductor package were observed. The defects were determined, for example, when de-wetting occurred due to poor fusion of the connection members, or when the first or second connection members were damaged in a laser drilling process to cause a decrease in volume, thereby resulting in no contact between the connection members. The results thereof are represented in Table 1. Further, the shapes of the connecting portions of the package on package were observed and illustrated in FIGS. 12 and 13. FIG. 12 illustrates the shapes of the connecting portions of the package on package of Experimental example 1. FIG. 13 illustrates the shapes of the defects of the connecting portions of the package on package of Comparison example 1.

TABLE 1

| | Experimental | Comparative |
|---|---|---|
| | example 1 | example 1 |
| First connection | Solder balls | Solder balls |
| members of lower | | |
| semiconductor package | | |
| Second connection | Cores + Cu + Ni + | Solder balls |
| members of upper | Solder layers | |
| semiconductor package | | |
| Defect ratio | 0/100 | 7/100 |

As represented in Table 1 above, no defect occurred in one hundred connection portions in Experimental example 1, whereas de-wetting and a decrease in volume of the solder balls occurred in seven connection portions of one hundred connection portions in Comparative example 1. Therefore, it can be seen that the connection portions in accordance with the exemplary embodiments can provide excellent connection between the packages and improve stacking yield.

Further, comparing the shapes of the connection portions, as shown in FIG. 12, the connection portions of Experimental example 1 include cores formed of a polymer and adhesive layers and have excellent wettability due to complete fusion of the first connection members and the conductive layers of the second connection members. On the other hand, as shown in FIG. 13, in some of the connection portions of Comparison example 1, there occurred de-wetting and no contact due to a decrease in volume of the solder balls.

While exemplary embodiments have been particularly shown and described, it will be understood by those of ordinary skill in the art that various changes in form and detail may be made therein without departing from the spirit and scope of the present inventive concept. The exemplary embodiments should be considered in a descriptive sense only and not for purposes of limitation.

1. A package on package comprising:
a first semiconductor package including a first substrate, a first semiconductor chip stacked on the first substrate, and a molding material formed on the substrate and molding the semiconductor chip;
a second semiconductor package including a second substrate, a second semiconductor chip stacked on the second substrate; and
a plurality of connection portions including a plurality of cores and a plurality of conductive fusion layers surrounding the plurality of cores, wherein the plurality of conductive fusion layers contact the upper surface of the first substrate through the first molding material and the lower surface of the second substrate.

2. The package on package of claim 1, wherein each of the plurality of cores is formed of a polymer.

3. The package on package of claim 1, wherein the plurality of cores is positioned closer to the first substrate than the second substrate.

4. The package on package of claim 1, wherein the plurality of cores is positioned closer to the second substrate than the first substrate.

5. The package on package of claim 1, wherein the each of the plurality of conductive fusion layers is formed of an alloy of lead and tin.

6. The package on package of claim 1, wherein the first semiconductor package further comprises the plurality of via holes in the first molding material.

7. The package on package of claim 6, wherein a part of the plurality of connection portions is included in the via holes.

8. The package on package of claim 1, wherein the first semiconductor chip is stacked on the first substrate via a plurality of chip bumps, and
wherein the plurality of chip bumps include the plurality of cores formed of a polymer, and the plurality of conductive layers surrounds the plurality of cores.

9. The package on package of claim 1, wherein each of the plurality of connection portions electrically connects the first semiconductor package and the second semiconductor package to each other, and wherein the first semiconductor package and the second semiconductor package are separated from each other by a predetermined distance.

10. A package on package comprising:
a first semiconductor package including a first substrate, a first semiconductor chip stacked on the first substrate, a plurality of first connection members on an upper surface of the first substrate and in a first molding material, and a plurality of via holes which respectively expose the plurality of first connection members through the first molding material;
a second semiconductor package including a second substrate, a second semiconductor chip stacked on the second substrate, and a plurality of second connection members on a lower surface of the second substrate; and
a plurality of connection portions formed by fusion of the plurality of first connection members and the plurality of second connection members,
wherein each of the plurality of connection portions connect the first semiconductor package with the second semiconductor package, and
wherein the plurality of connection portions include a plurality of cores and a plurality of conductive fusion layers surrounding the plurality of cores, and the plurality of conductive fusion layers contact the upper surface of the first substrate and the lower surface of the second substrate.

11. The package on package of claim 10, wherein each of the plurality of cores is formed of a polymer.

12. The package on package of claim 10, wherein each of the plurality of cores is formed of a polymer, and wherein the plurality connection members further includes a plurality of conductive layers which surround the plurality of cores.

13. The package on package of claim 12, wherein each of the plurality of second connection members is formed of a same material as the plurality of conductive layers of the plurality of first connection members.

14. The package on package of claim 12, wherein each of the plurality of conductive fusion layers is formed by fusion of the plurality of conductive layers of the plurality of first connection members and the plurality of second connection members.

15. The package on package of claim 14, wherein the plurality of conductive layers and the plurality of second connection members are formed of an alloy of lead and tin.

16. A package on package comprising:
a first semiconductor package including a first substrate and a first semiconductor chip stacked on the first substrate;
a second semiconductor package including a second substrate and a second semiconductor chip stacked on the second substrate; and
a plurality of connection portions which electrically connect the first semiconductor package with the second semiconductor package, wherein each of the plurality of connection portions comprises a core and a conductive fusion layer surrounding the core, wherein the conductive fusion layer contacts an upper surface of the first substrate and a lower surface of the second substrate.

17. The package on package of claim 16, wherein each of the plurality of connection portions further comprises at least one adhesive layer which surrounds the core and is between the core and the conductive fusion layer.

18. The package on package of claim 17, wherein the at least one adhesive layer is formed of at least one element selected from a group consisting of aluminum (Al), titanium (Ti), vanadium (V), chromium (Cr), manganese (Mn), iron (Fe), copper (Cu), cobalt (Co), nickel (Ni), zirconium (Zr), niobium (Nb), molybdenum (Mo), palladium (Pd), silver (Ag), cadmium (Cd), indium (In), tin (Sn), tantalum (Ta), tungsten (W), platinum (Pt) and gold (Au).

19. The package on package of claim 18, wherein each of the plurality of connection portions further comprises a conductive layer which surrounds the core and is between the at least one adhesive layer and the conductive fusion layer.

20. The package on package of claim 19, wherein the conductive layer is formed of at least one element selected from a group consisting of aluminum, titanium, vanadium, chromium, manganese, iron, cobalt, nickel, copper, zinc, zirconium, niobium, molybdenum, palladium, silver, cadmium, indium and tin.
